(19) United States
(12) Patent Application Publication
(10) Pub. No.: US 2021/0335651 A1
(43) Pub. Date: Oct. 28, 2021

(54) APPARATUS FOR EXCHANGING AN ARTICLE OF A SEMI-CONDUCTOR PROCESS AND A METHOD FOR EXCHANGING THE ARTICLE USING THE SAME

(71) Applicant: Adaptive Plasma Technology Corp., Icheon-si (KR)

(72) Inventors: Woo Hyung CHOI, Seongnam-si (KR); Sang Woo LEE, Suwon-si (KR)

(21) Appl. No.: 17/015,533

(22) Filed: Sep. 9, 2020

(30) Foreign Application Priority Data
Apr. 23, 2020 (KR) 10-2020-0049072

(51) Int. Cl. H01L 21/687; B25J 9/16; B25J 19/02

(52) U.S. Cl. CPC H01L 21/68721; B25J 19/021; B25J 9/1697

(57) ABSTRACT

Provided is an apparatus for exchanging an article of a semi-conductor process and a method for exchanging the article using the same. The apparatus for exchanging an article in a semiconductor process, comprising: a loading unit located at a finger coupled to a transferring means for loading the article'an operation controlling unit displaced at the loading unit and having a communicating means; and at least one vision unit.

### BACKGROUND OF THE INVENTION

### Field of the Invention

The present invention relates to an apparatus for exchanging an article of a semi-conductor process and a method for exchanging the article using the same, in particular relates to the apparatus for detecting a exchanging position of the article and fixing the article at a predetermined location in the semi-conductor process and the method for exchanging the article with the same.

### Description of the Related Art

A consumable article such as an edge ring used in a semiconductor manufacturing field should be replaced periodically. The edge ring may have a function to restrict a plasma or gas flow at a wafer edge for enhancing a process uniformity or reliability. For replacing the edge ring, an inner volume of a chamber is made an atmospheric pressure condition for removing a lid. But, if the replacement of the edge ring is performed in a vacuum condition by a robot, then a time for replacement and back-up of a facility may be reduced to improve productivity. Korean patent publication No. 10-2017-0054248 discloses a cluster tool assembly for removing a consumable part and replacing the part in a processor module installed at the cluster tool assembly. And also, Korean patent publication No. 10-2011-0056841 discloses a load lock chamber including an aligning apparatus for a wafer. It is advantageous in a manufacturing efficiency that a certain change of a semiconductor processing facility is minimized and the time for exchanging decreases for replacing the article. But, the prior art does not disclose a technique with the advantage.

### PURPOSE OF THE INVENTION

The purpose of the present invention is to provide with an apparatus for detecting an exchanging position of an article to fix the article at a predetermined location in the semi-conductor process and the method for exchanging the article with the same.

### SUMMARY OF THE INVENTION

In one embodiment of the present invention, an apparatus for exchanging an article in a semiconductor process comprises a loading unit located at a finger coupled to a transferring means for loading the article; an operation controlling unit displaced at the loading unit and having a communicating means; and at least one vision unit.

In other embodiment of the present invention, the article is an edge ring coupled to a wafer.

In another embodiment of the present invention, at least two positions in an exchanging area are detected by the vision unit.

In still another embodiment of the present invention, a pair of vision units are displaced along a line vertical to a moving line of the article.

In still another embodiment of the present invention, a method for exchanging an article of a semiconductor process comprises moving an exchanging module to an exchanging location; exiting a replaced article by the exchanging module; loading a replacing article on the exchanging module; detecting a position relative to a fixing object by a vision unit installed at the exchanging module; aligning the exchanging module based on a detecting information; and placing the replacing article in a predetermined position.

### BRIEF DESCRIPTION OF THE DRAWINGS

FIG. 1 shows an exemplary embodiment of an apparatus for exchanging an article in a semiconductor process according to the present invention.

FIG. 2 shows an exemplary embodiment of an application according to the present invention.

FIG. 3 shows other exemplary embodiment of an apparatus according to the present invention.

FIG. 4 shows another exemplary embodiment of an apparatus according to the present invention.

FIG. 5 shows an exemplary embodiment of a process for exchanging an edge ring according to present invention.

FIG. 6 shows an exemplary embodiment of a method for exchanging an article according to present invention.

FIG. 7 shows other exemplary embodiment of a method for exchanging an article according to present invention.

### DETAILED DESCRIPTION OF EXEMPLARY EMBODIMENTS

Exemplary embodiments of the present invention will be described herein below with reference to the accompanying drawings.

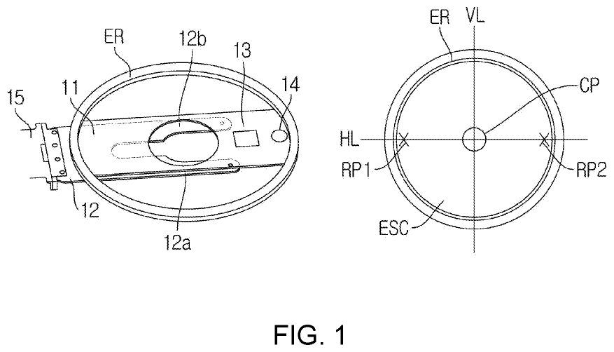

FIG. 1 shows an exemplary embodiment of an apparatus for exchanging an article in a semiconductor process according to the present invention.

Referring to FIG. 1, an apparatus for exchanging an article in a semiconductor process comprises a loading unit 11 located at a finger 12 coupled to a transferring means 15 for loading the article; an operation controlling unit 13 displaced at the loading unit and having a communicating means; and at least one vision unit 14.

The article ER may be an edge ring having a function that a wafer can be fixed firmly at a predetermined position in a course of a semiconductor process. Various consumable parts or a part required to be exchanged may be replaced using the apparatus according to the present invention. A replaced article or part may be a used article or a part to be removed due to a using date or a defect, and a replacing part may be a new part to substitute for the replaced part. The apparatus for exchanging the article may be transferred into a process chamber by an automatic delivering device such as a robot arm. The apparatus may be coupled to a finger 12 coupled to a transferring means 15, or the apparatus may become one part of the finger 12. For example, the apparatus may have a groove, a protrusion, a magnetic means, a locking part or the like for being coupled to the finger 12. For example, the finger 12 may have a pair of finger hands 12a, 12b extending in parallel and separated each other. And a loading unit 11 having a rectangular flat shape, a circular flat shape or the like may be coupled to the finger 12. The loading unit 11 may have various shapes for loading the article ER. The loading unit 11 may be transferred at various locations or positions by the transferring means 15, for example, the loading unit 11 may be transferred to an electrostatic chuck ESC installed within the process chamber. An operation controlling unit 13 may be displaced at the loading unit 11. The operation controlling unit 13 may have a structure of an electronic chip, and the operation controlling unit 13 may detect an operating condition of the loading unit 11, or the operation controlling unit 13 may control operations of various electronic elements or electronic devices. And also, the operation controlling unit 13 may comprise a communicating means such as a near filed communication means for communicating a controlling apparatus in the outside. For example, the operation controlling unit 13 may detect a moving condition of the article ER or an exchanging step of the ER to transmit the condition to the outside controlling apparatus. For example, a position information of the article ER obtained by the vision unit 14 may be transmitted to the outside controlling apparatus via the communicating means under the operation of the operation controlling unit 13. For example, the vision unit 14 such as a camera may be installed at a front of the loading unit 11. The vision unit 14 may be located at the loading unit 11 to obtain a predetermined position image with the article loaded. For example, the vision unit 14 may be installed under the loading unit 11 to obtain an image of the position where the article ER has to be fixed. The location of the article ER may be verified with the image, and a position for fixing the article ER in the exchanging course may be detected and verified. The verification of the position for fixing the article ER may be performed in a course of exiting the replaced article ER or placing the replacing article ER. For example, the loading unit 11 may move to the electrostatic chuck ESC for exchanging the article ER. For example, the loading unit 11 may move along a firs fixing reference line HL corresponding to x-axis, and a first image may be obtained in the course of moving. And at the same time, the position of the article ER may be checked. And then, the loading unit may move along the same path or a path that a moving position can be detected, and an image of a second detecting point PR2 may be obtained by the vision unit 14. And the images of the first and the second detecting point PR1, PR2 may be transmitted to a transferring control apparatus for regulating the transferring means 15 or the finger 12 via the communicating means. And a central point CP corresponding to a crossing point of the first fixing reference line HL and the second fixing reference may be verified. The central point CP may be compared with the article position verified by the first detecting point and the second detecting point RP1, RP2 to regulate the position of the loading unit 11. And the replaced article may be exit or the replacing article is placed. The location detection of the article ER by the vision unit 14 and the position control of the loading unit 11 may be performed in various ways, not limited to.

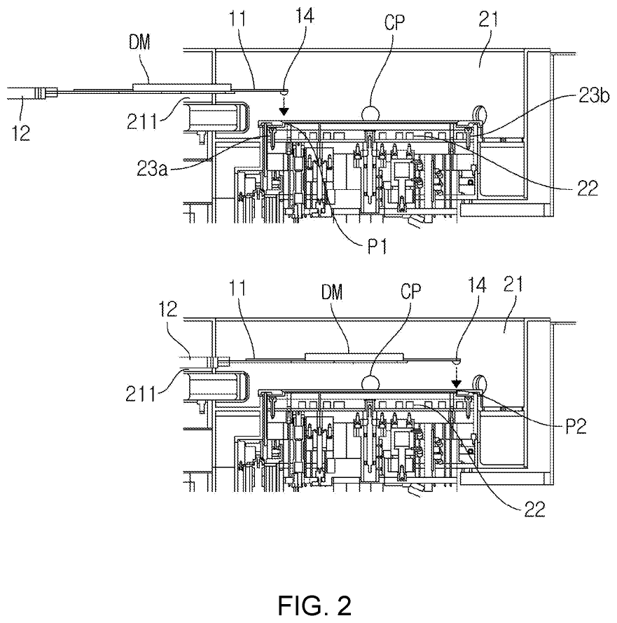

FIG. 2 shows an exemplary embodiment of an application according to the present invention.

Referring to FIG. 2, the article may be exit from the process chamber 21 or may enter the process chamber by the loading unit 11 coupled to the finger 12. A fixing chuck 22 for fixing a wafer or the like may be installed within the process chamber 21, and the fixing chuck 22 may be the electrostatic chuck. An opening 211 may be formed at the process chamber 21, and the finger 12 may enter the process chamber 21 through the opening 211 for exchanging the article. A separating means 23a, 23b such as a lift pin may be installed at the fixing chuck 22, and the article may be separated from the fixing chuck 22 by the separating means 23a, 23b. For locating the exchanging article on the fixing chuck 22, the article may be place on the separating means 23a, 23b, and then the separating means 23a, 23b may move downwardly for fixing the article around the wafer. The first detecting position P1 image may be obtained by the vision unit 14, as the loading unit 11 accesses to the fixing chuck 22 through the opening 211. The vision unit 14 may be coupled to a lower surface of the loading unit 11. And the vision unit 14 may obtain the first detecting position image, while the loading unit 11 is over the fixing chuck 22. The first detecting position P1 may become various positions which is detectable at different angle by the vision unit 14 and is a peripheral part of the fixing chuck 22. And also, the first detecting position P1 is not necessary to be predetermined. If the loading unit 11 is located over the fixing chuck 22, an image of the second detecting position P2 may be obtained, as shown in lower part of FIG. 2. The second detecting position P2 may be selected as an end point of the fixing chuck 22, and the second detecting position P2 may face the first detecting position P1 at the fixing chuck 22. If the images of the first and second detecting position P1, P2 are obtained by the vision unit 14, the image information may be transmitted to an exchanging control apparatus through a detecting module DM. The detecting module DM may have a function similar to the operation controlling unit in FIG. 1. And the detecting module DM may comprise an image treating means, a storing means and a communicating means. If the first and second detecting positions P1, P2 are verified, the central position CP can be determined. Hence, a present location of the loading unit 11 and a position relative the central position CP may be verified to determine an exact location for removing the consumable article or fixing the exchanging article. Therefore, the location accuracy may be enhanced in the process of exchanging, and an exchanging error may be prevented previously.

A plurality of detecting positions P1, P2 may be detect for determining a location of the loading unit 11 relative to that of the fixing chuck 22.

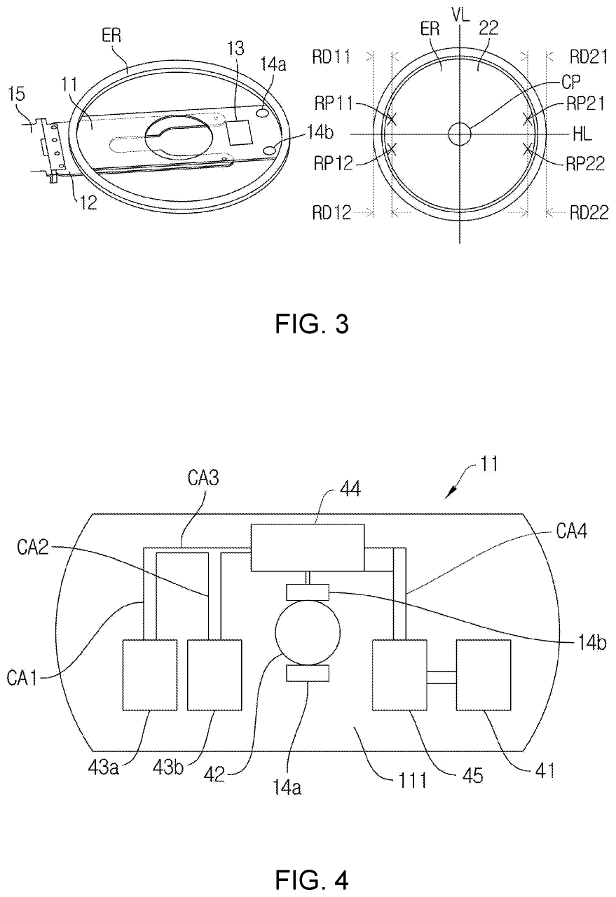

FIG. 3 shows other exemplary embodiment of an apparatus according to the present invention.

Referring to FIG. 3, a pair of vision units 14a, 14b may be installed at the loading unit 11, and four positions of the fixing chuck 22 may be detected by the vision units 14a, 14b. The pair of vision units 14a, 14b may be located at the lower surface of the loading unit 11 along a center line in a longitudinal direction and facing each other.

When the article ER such as the edge ring is loaded on the loading unit 11, the finger 12 coupled to the transferring means 15 such as a robot arm may move to the fixing chuck 22. And loading unit 11 may move to the fixing chuck 22, together with the movement of the finger 12. The loading unit 11 may move along a first fixing reference line HL formed in the fixing chuck 22 virtually. When a front part of the loading unit 11 reaches a fore part of the fixing chuck 22, Images of detecting positions RP11, RP12 located at the front of the fixing chuck 22 may be obtained by the first and second vision unit 14a, 14b under the control of the operation control unit 13. And then, the load unit 11 may move over the fixing chuck 22, and the front of the loading unit 11 may be located at other part of the fixing chuck 22 to obtain detecting positions RP21, RP22 in the rear parts of the fixing chuck 22. The position of the loading unit 11 or the article ER relative to the first and second reference fixing line HL, VL may be verified based on four detecting positions RP11, RP12, RP21, RP22. For example, the location of the article ER or distances RD11, RD12, RD21, RD22 among four positions relative to a virtual location may be calculated. And a moving distance or a rotating angle may be calculated in order that a center of the article is identical to that of the fixing chuck 22 based on the calculated values. And the loading unit 11 may be transferred to be arranged based on the calculated distance or angle, accordingly the article ER may be located accurately on the fixing chuck 22. An arranging reference may be set in various ways, not limited to.

FIG. 4 shows another exemplary embodiment of an apparatus according to the present invention.

Referring to FIG. 4, the loading unit 11 may have an electric board shape where various elements or electronic components are mounted, and have a means coupled to the finger. The loading unit 11 may comprise a loading body in a flat shape; a plurality of controlling chips 43a, 43b, 14a, 14b, 42, 44 mounted on the loading body 111; and a power source such as a battery to supply an electric power.

For example, a detecting body 43a or a regulating unit 43b may be installed on the loading body 111, and the pair of vision units 14a, 14b and a location controlling unit 42 for controlling the vision units 14a, 41b displaced at facing locations each other may be installed on the loading body 111. And also, a communicating chip 45 may be installed on the loading body 111, and each device may be electrically connected to a central processing unit 44 such as a micro-processor by an operational cable CA1, CA2, CA3, CA4. The loading unit 11 may have a closed structure and may operate independently. The vision units 14a, 14b may be directed to a lower direction, and a focus direction or a focus distance for obtaining an image may be regulated. And also, a sealing cover for closing may be coupled to a upper part of the loading body 111, and the sealing cover may seal the loading body 111 and may have a structure on the upper part of which an electronic component or the like may be installed. Loading unit 11 may have various structures for loading the article, transferring to the fixing chuck, and detecting the positions of the fixing chuck, not limited to.

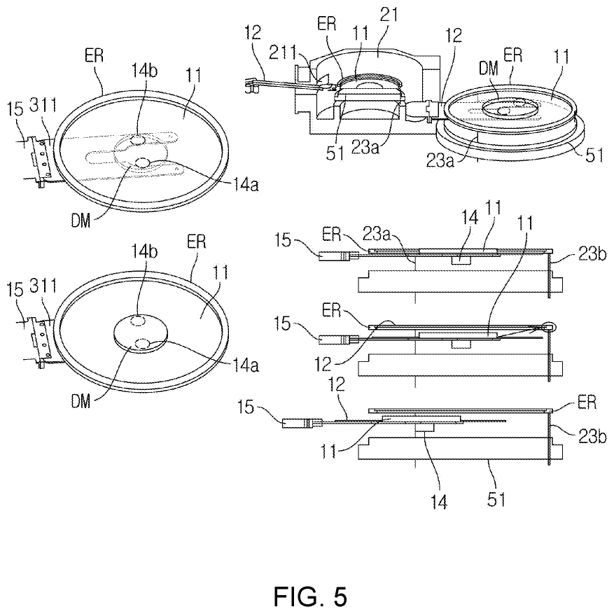

FIG. 5 shows an exemplary embodiment of a process for exchanging an edge ring according to present invention.

Referring to FIG. 5, the article ER such as a removed edge ring corresponding to a consumable component may be kept at an electrostatic chuck 51, and the article ER may be elevated upwardly by the separating means 23a, 23b such as the lift pins. And a loading unit position relative to the electrostatic chuck 51 may be verified by the vision unit 14 installed at the loading unit 11 and transferred into the process chamber 21 through the opening 211. And the loading unit 11 may be transferred under the elevated article ER for loading, and the article ER loaded on the loading unit 11 may be discharged the outside of the process chamber 21. If the removed article is removed from the electrostatic chuck 51, the loading unit 11 where a replacing article ER is loaded may be transferred into the process chamber through the opening 211 for replacing the removed article ER. In FIG. 5, the loading unit 11 may have a circular flat shape in general and the article may be an edge ring for a wafer. The loading unit position relative to the electrostatic chuck 51 may be verified by the pair of vision units 14a, 14b installed under the loading unit 11. For example, two positions or four positions of the front and rear part of the electrostatic chuck 51 may be detected. And the article position relative to the electrostatic chuck 51 may be determined, and the loading unit 11 may be transferred in order that the center position of the article ER may be consistent with that of the electrostatic chuck 51. If the loading unit 11 is located at a predetermined position, then the separating means 23a, 23b such as the lift pin may be lifted to elevate the article ER, and the loading unit 11 may be transferred under the article. Thereafter, the replacing article ER may be placed on the separating means 23a, 23b, and the loading unit 11 may come down to be transferred outside the process chamber 21. And then, the separating means 23a, 23b may move downwardly for fixing the article at the electrostatic chuck 51. Various consumable articles may be transferred to a predetermined place for fixing by loading unit 11, not limit to.

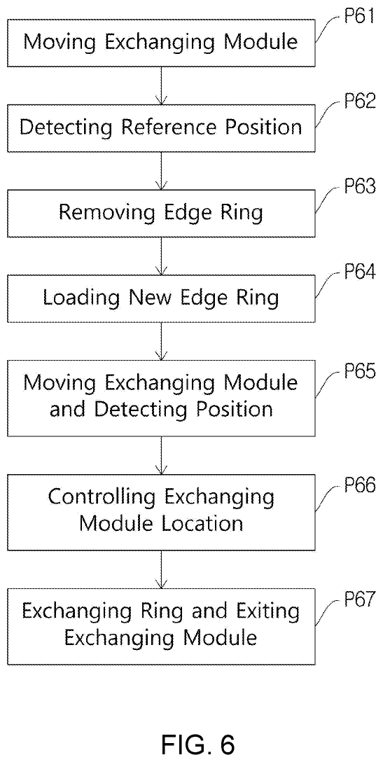

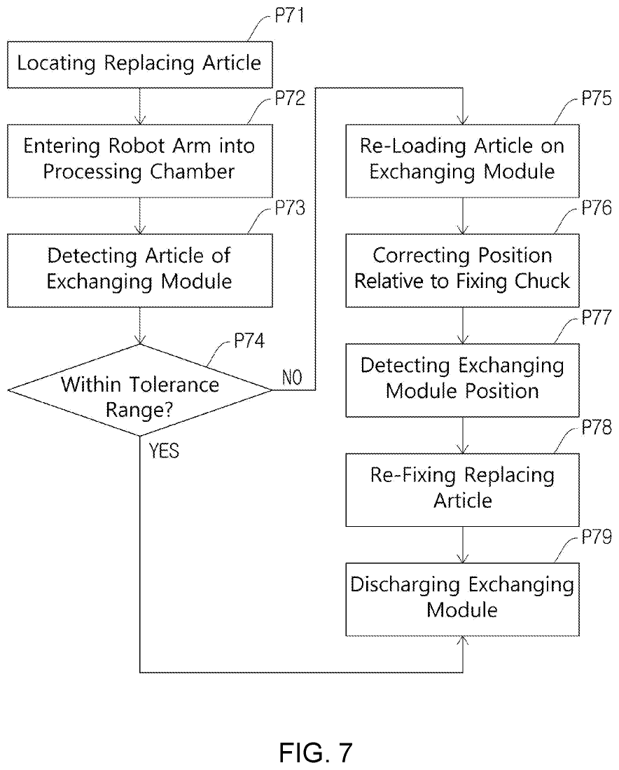

FIG. 6 shows an exemplary embodiment of a method for aligning an article according to present invention.

Referring to FIG. 6, A method for aligning an article of a semiconductor process comprises moving an exchanging module to an exchanging location P61; exiting a removed article by the exchanging module P63; loading a replacing article on the exchanging module P64; detecting a position relative to a fixing object by a vision unit installed at the exchanging module P65; aligning the exchanging module based on a detecting information P66; and placing the replacing article in a predetermined position P67. The exchanging module may be the loading unit described above, and the exchanging module may comprise a vision unit, a communicating means and various controlling means. The exchanging module may be transferred into the process chamber P61, and a reference position for removing a replaced article may be detected P62. The exchanging module may be moved to the reference position, the replaced article may be loaded on the exchanging module for being discharged outside the process chamber P63. If the replaced article is removed P63, then a replacing article may be loaded on the exchanging module to be transferred to a fixing object such as an electrostatic chuck where the article is fixed P64. A replacing article position relative to the fixing object may be verified by the vision unit installed at the exchanging module P65. A position of the exchanging module may be controlled based on the verified position P66, and the exchanging module may be transferred to a predetermined position. Then, the article may be fixed at the fixing object by the exchanging module, and the exchanging module may be moved outside the process chamber. it may happen that the article position relative to the fixing object is difficult to be detected with the article loaded or a detected information is difficult to be transmitted. In such case, the position may be detected after the replacing article is fixed at the fixing object.

FIG. 7 shows other exemplary embodiment of a method for aligning an article according to present invention.

Referring to FIG. 7, the method for aligning an article of a semiconductor process may further comprise detecting the article position relative to the fixing object after the replacing article is fixed. As discussed in FIG. 6, the article position relative to the fixing chuck may be detected previously, and the replacing article may be fixed basted on the detected information. In the meanwhile, the article position relative to the fixing chuck may be detected after the replacing article is located on the fixing chuck. Specifically, the method for exchanging the article may comprise locating the article on the fixing chuck, after the replaced article is removed to be discharged outside the process chamber 71; detecting the article position relative to the fixing chuck by the vision unit installed at exchanging module 73; judging whether the article is located on the fixing chuck accurately in a tolerance permissible error range P74; loading the article on the exchanging module depending on the judgement P75; correcting the reference position where the article has to be fixed P76; and locating the article again on the fixing chuck by the exchanging module P78. If the replacing article is fixed on the fixing chuck P71, then the same or a different exchanging module may enter the process chamber P72 to detect the replacing article position relative to the fixing chuck P73. The reference position may be verified by the pair of vision units obtaining four images, as discussed above P74. If the article is fixed on the fixing chuck within the tolerance permissible error range YES, then the exchanging module may be moved outside of the process chamber P79. On the other hand, if the article is out of the tolerance permissible error range NO, then the lift pin may be lifted to elevate the replacing article and the article may be loaded on the exchanging module P75. Thereafter, the reference position for fixing the article may be corrected P76. Specifically, the exchanging module position relative to the fixing chuck may be detected again based on the present position of the exchanging module P77. And then, the article may be located again based on the corrected position and the detected position P78. Then, the exchanging module may exit from the process chamber P79. If necessary, the replacing article position relative to the fixing chuck again, and the position may be corrected. As discussed above, it improves the exchanging accuracy that the article position is verified again after the article is fixed on the fixing chuck. The re-location of the article may be performed in various ways, not limited to.

While the present invention has been particularly shown and described with reference to exemplary embodiments thereof, it will be understood by those skilled in the art that various changes in form and details may be made therein without departing from the spirit and scope of the present invention as defined by the appended claims.

What is claimed is:

1. An apparatus for exchanging an article in a semiconductor process, comprising:
a loading unit located at a finger coupled to a transferring means for loading the article'
an operation controlling unit displaced at the loading unit and having a communicating means; and
at least one vision unit.

2. The apparatus according to claim 1, wherein the article is an edge ring coupled to a wafer.

3. The apparatus according to claim 1, wherein at least two positions in an exchanging area are detected by the vision unit.

4. The apparatus according to claim 1, wherein a pair of vision units are displaced along a line vertical to a moving line of the article.

5. A method for aligning an article of a semiconductor process, comprising
moving an exchanging module to an exchanging location;
exiting a replaced article by the exchanging module;
loading a replacing article on the exchanging module;
detecting a position relative to a fixing object by a vision unit installed at the exchanging module;
aligning the exchanging module based on a detecting information; and
placing the replacing article in a predetermined position.
